(19) United States
(12) Patent Application Publication
(10) Pub. No.: US 2026/0064310 A1
(43) Pub. Date: Mar. 5, 2026

(54) DATA READING METHOD AND DEVICE

(71) Applicant: Smarter Silicon (Shanghai) Technologies Co., Ltd., Shanghai (CN)

(72) Inventor: Peng LI, Shanghai (CN)

(21) Appl. No.: 19/310,139

(22) Filed: Aug. 26, 2025

(30) Foreign Application Priority Data
Aug. 30, 2024 (CN) 202411217446.X

(51) Int. Cl. G06F 3/06

(52) U.S. Cl. CPC G06F 3/0655; G06F 3/0604; G06F 3/0679

(57) ABSTRACT

A data reading method includes determining a data reading mode for a data array, determining, based on the data reading mode, an obtaining order for obtaining data in different directions in the data array, and a plurality of loop counting structures for obtaining the data in the different directions, and performing, according to the obtaining order, counting sequentially through corresponding ones of the loop counting structures. A position of target data in the data array is determined based on counting of the loop counting structures.

### CROSS-REFERENCE TO RELATED APPLICATION

This application claims priority to Chinese Patent Application No. 202411217446.X, filed on Aug. 30, 2024, the entire content of which is incorporated herein by reference.

### FIELD OF THE TECHNOLOGY

The present disclosure relates to a field of data processing, and in particular to a data reading method and device.

### BACKGROUND

Artificial intelligence models are built using a variety of network models, for example, convolutional neural network model CNN that uses matrix-based calculation, attention-based deep learning model Transformer, and sparse Transformer. These three models have different ways of reading data, and hence three different circuits need to be set up in the chip to read data from different models, which leads to unwanted complexity in the hardware design of the chip and increased chip area.

### SUMMARY

In accordance with the disclosure, there is provided a data reading method including determining a data reading mode for a data array, determining, based on the data reading mode, an obtaining order for obtaining data in different directions in the data array, and a plurality of loop counting structures for obtaining the data in the different directions, and performing, according to the obtaining order, counting sequentially through corresponding ones of the loop counting structures. A position of target data in the data array is determined based on counting of the loop counting structures.

Also in accordance with the disclosure, there is provided a data reading device including a plurality of loop counting structures corresponding to different data reading modes, and a processor configured to determine a data reading mode for a data array, determine, based on the data reading mode, an obtaining order for obtaining data in different directions in the data array, and the plurality of loop counting structures for obtaining the data in the different directions, and perform, according to the obtaining order, counting sequentially through corresponding ones of the loop counting structures, a position of target data in the data array being determined based on counting of the loop counting structures.

Also in accordance with the disclosure, there is provided a non-transitory computer-readable storage medium storing instructions that, when executed by a processor, cause the processor to determine a data reading mode for a data array, determine, based on the data reading mode, an obtaining order for obtaining data in different directions in the data array, and a plurality of loop counting structures for obtaining the data in the different directions, and perform, according to the obtaining order, counting sequentially through corresponding ones of the loop counting structures, a position of target data in the data array being determined based on counting of the loop counting structures.

### BRIEF DESCRIPTION OF THE DRAWINGS

To illustrate the technical solutions in certain embodiments of the present disclosure, accompanying figures are introduced. The figures described herein below reflect certain embodiments. Persons skilled in the technical field may derive other figures based on these figures without inventive effort.

FIG. 1 is a schematic flowchart of a data reading method according to certain embodiments of the present disclosure;

FIG. 2A is a schematic diagram of a data reading method corresponding to deep learning model Transformer based on an attention mechanism according to certain embodiments of the present disclosure;

FIG. 2B is a schematic diagram of a data reading method corresponding to sparse Transformer model according to certain embodiments of the present disclosure;

FIG. 2C is a schematic diagram of a data reading method corresponding to convolutional neural network model CNN according to certain embodiments of the present disclosure;

FIG. 3 is a schematic flowchart of a data reading method according to certain embodiments of the present disclosure;

FIG. 4 is a flowchart of a data reading method according to certain embodiments of the present disclosure;

FIG. 5A is a schematic diagram of a method for obtaining data corresponding to deep learning model Transformer based on an attention mechanism according to certain embodiments of the present disclosure;

FIG. 5B is a schematic diagram of a method for obtaining data corresponding to deep learning model Transformer based on an attention mechanism according to certain embodiments of the present disclosure;

FIG. 5C is a schematic diagram of data obtaining for convolutional neural network model (CNN) according to certain embodiments of the present disclosure;

FIG. 6 is a schematic structural diagram of a data reading device according to certain embodiments of the present disclosure;

FIG. 7A is a circuit diagram for obtaining data from deep learning model based on an attention mechanism according to certain embodiments of the present disclosure;

FIG. 7B is a circuit diagram for obtaining data from sparse Transformer model according to certain embodiments of the present disclosure;

FIG. 7C is a circuit diagram for obtaining data from convolutional neural network model CNN according to certain embodiments of the present disclosure; and

FIG. 7D is a circuit diagram of a data reading device according to certain embodiments of the present disclosure.

### DETAILED DESCRIPTION

The following describes certain embodiments of the present disclosure with reference to the accompanying drawings. The terms used in the detailed description are to explain certain embodiments and are not intended to limit the present disclosure.

Persons skilled in the technical field appreciate that, with technological advancements and the emergence of new scenarios, the technical solutions provided by certain embodiments are applicable to similar technical problems.

When applicable, the terms “first” and “second” and the like are used to distinguish similar objects and are not necessarily used to describe a particular order. These terms may be interchangeable and may be used to distinguish objects with the same or similar attributes. Furthermore, terms such as “including” and “comprising” and any variations thereof are intended to cover non-exclusive inclusions, such that a process, method, system, product, or apparatus is not necessarily limited to those elements but may include other elements not expressly listed or inherent to such process, method, product, or apparatus.

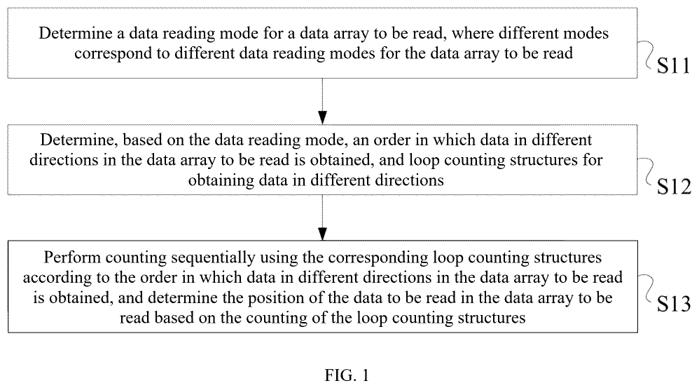

The present disclosure in certain embodiments discloses a data reading method, the flow chart of which is shown in FIG. 1. The method includes:
S11: Determine a data reading mode for a data array to be read (also referred to as “target data array”), where different modes correspond to different data reading modes for the data array to be read;
S12: Determine, based on the data reading mode, an order in which data in different directions in the data array to be read is obtained, and loop counting structures for obtaining data in different directions;
S13: Perform counting sequentially using the corresponding loop counting structures according to the order in which data in different directions in the data array to be read is obtained, and determine the position of the data to be read (also referred to as “target data”) in the data array to be read based on counting of the loop counting structures.

The order in which data in different directions in the data array to be read is obtained is also referred to as a “data obtaining order” of the data array to be read, i.e., the data obtaining order of the target data array.

Artificial intelligence models are constructed using various network models, for example, convolutional neural network model CNN using matrix-based calculation, attention-based deep learning model Transformer, and sparse Transformer. These three models use different data reading methods.

To implement data reading using different modes for different models, the chip may need to have circuits corresponding to each model. This requires multiple different circuits within the chip to enable data reading from multiple different models, which increases the complexity of the chip's internal hardware design and the chip area.

In certain embodiments, the present disclosure provides loop counting structures within the loop counter. When determining the data reading mode corresponding to the data to be read, the corresponding loop counting structure is selected from two or more or multiple loop counting structures based on the data reading mode to read the data to be read. The loop counting structures are used to read data corresponding to any data reading mode. Reusing loop counting structures reduces circuit space occupied by the loop counter, eliminating the need for a separate circuit for each data reading mode and reducing the complexity of the circuit structure within the loop counting structure.

In certain embodiments, when determining that data to be read is in the form of a data array, the array corresponding to the data to be read, the data reading mode corresponding to the data array to be read, is determined. Different models have different data reading modes for data arrays to be read.

In certain embodiments, convolutional neural network model CNN corresponds to a first data reading mode, deep learning model Transformer based on the attention mechanism corresponds to a second data reading mode, and sparse Transformer corresponds to a third data reading mode. The first, second, and third data reading modes read data in different ways. Other models may have corresponding data reading modes, which are not listed here.

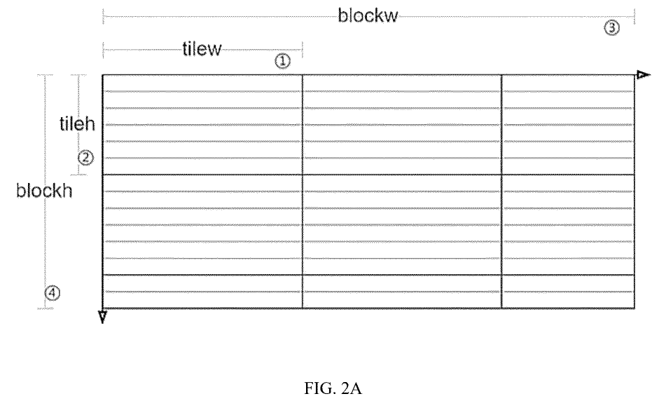

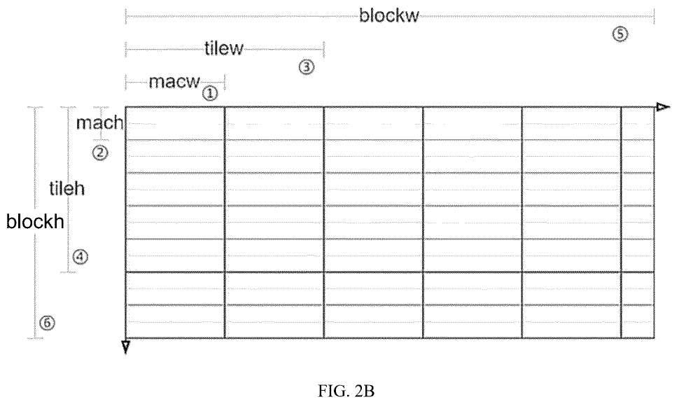

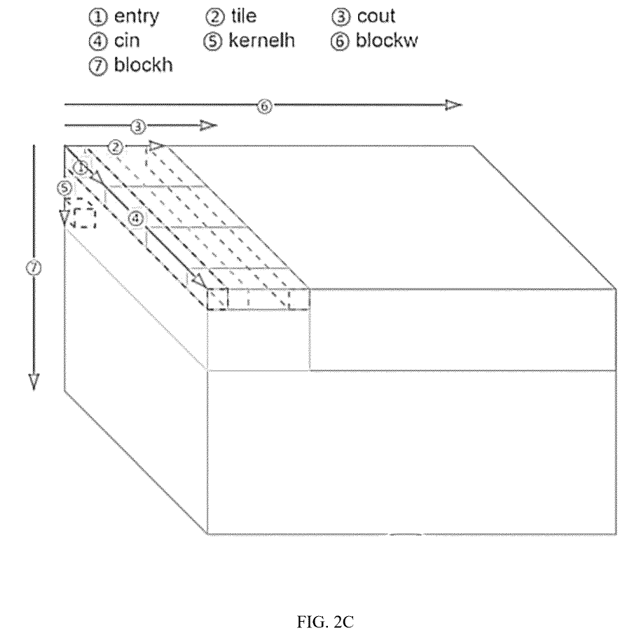

Taking Transformer, a deep learning model based on the attention mechanism, as an example, its data reading method is shown in FIG. 2A. From the data array, data is retrieved in row-column order, with the smallest granularity being the tile, and the entire block is retrieved. For sparse Transformer, the data reading method is shown in FIG. 2B. From the data array, data is retrieved in row-column order, with the smallest granularity being the Mac. After transposition, it is stored in the dynamic random access memory (DRAM). A full tile is retrieved, and the entire block is retrieved. For convolutional neural network model CNN, the data reading method is shown in FIG. 2C. From the data array, Cin is first retrieved, filling an entry. Then, data is retrieved from Kernelh, and then from BlockW, taking Tileh rows of data to form a tile and then starting calculation. The entire block of data is retrieved.

When determining that data to be read requires reading, the model to which the data corresponds is determined. Different models correspond to different data reading modes, so the appropriate data reading mode is determined.

Different data reading modes use different loop counting structures when reading data. Therefore, after determining the data reading mode corresponding to the data array of the data to be read, the order of obtaining data in different directions in the data array when reading data under the data reading mode is determined, such as: first obtaining data in the Cin direction, then obtaining data in the KernelH direction, then obtaining data in the BlockW direction, and then obtaining data in the BlockH direction; or, first obtaining data in the BlockW direction, then obtaining data in the BlockH direction, or the like.

While determining the order in which data in different directions in the data array is obtained, the system determines the loop counting structure corresponding to each direction of data to be obtained. In certain embodiments, each direction of data obtaining corresponds to a loop counting structure. Different data reading modes correspond to different directions of data to be obtained. Therefore, after determining the data reading mode, the directions of data to be obtained in that data reading mode are determined, and the corresponding loop counting structure is obtained for each direction of data to be obtained. The loop counting structure then determines the position of the data to be read in the data array based on counting of the loop counting structure, thereby enabling the obtaining of data in different directions from the data array to be read.

The loop counting structures may be pre-set. After determining the data reading mode for the data array corresponding to the data to be read, the direction of the data to be read in the data array is determined. Based on the determined direction, the corresponding loop counting structure is retrieved from the pre-set loop counting structures. Counting is performed sequentially using the corresponding loop counting structures in the order in which the data in different directions from the data array are obtained, thereby enabling the obtaining of data in different directions from the data array to be read.

In certain embodiments, a first loop counting structure, a second loop counting structure, a third loop counting structure, a fourth loop counting structure, a fifth loop counting structure, and a sixth loop counting structure are pre-set. The model corresponding to the data array to be read is the first model. The directions of the data array to be read in the data reading mode corresponding to the first model are the first direction, the third direction, and the fourth direction. The first loop counting structure corresponding to the first direction, the third loop counting structure corresponding to the third direction, and the fourth loop counting structure corresponding to the fourth direction are determined. The order of obtaining data in different directions in the data array is determined to be: first direction→third direction→fourth direction. The loop counting structures are then arranged according to the obtaining order as: first loop counting structure→third loop counting structure→fourth loop counting structure. Counting is performed sequentially in this order for the three loop counting structures until all the three loop counting structures finish counting thereby enabling the reading of data in the first direction, the third direction, and the fourth direction in the data array.

For different data to be read, since the corresponding models are different, the corresponding data reading modes are different, so the loop counting structures to be called are also different. Therefore, when reading different data to be read, it is possible to reuse or repeat using the pre-set loop counting structures in different directions. There is no need to set up a circuit dedicated to loop counting when reading data for each data reading mode, which saves space in the circuit.

The data reading method disclosed in certain embodiments determines a data reading mode of a data array to be read, where the data arrays to be read corresponding to different models have different data reading modes; based on the data reading mode, determines the obtaining order of data in different directions in the data array to be read, and the loop counting structures for obtaining data in different directions; according to the obtaining order of data in different directions in the data array to be read, counting is performed in sequence through the corresponding loop counting structures, and the position of the data to be read in the data array to be read is determined by counting the loop counting structures. This scheme sets the loop counting structures, and when data in the data array is to be read, obtains the corresponding loop counting structures based on the data reading mode of the data array to be read, and counts in sequence through the corresponding loop counting structures to determine the position of the data to be read in the data array to be read, thereby realizing the reading of data in different data reading modes by reusing the loop counting structures. By reusing the loop counting structures, there is no need to set a separate and independent data reading process composed of multiple loop counting structures for each data reading mode, thereby reducing the space occupied by the circuit of the loop counter composed of the multiple loop counting structures and reducing the hardware design complexity inside the loop counter.

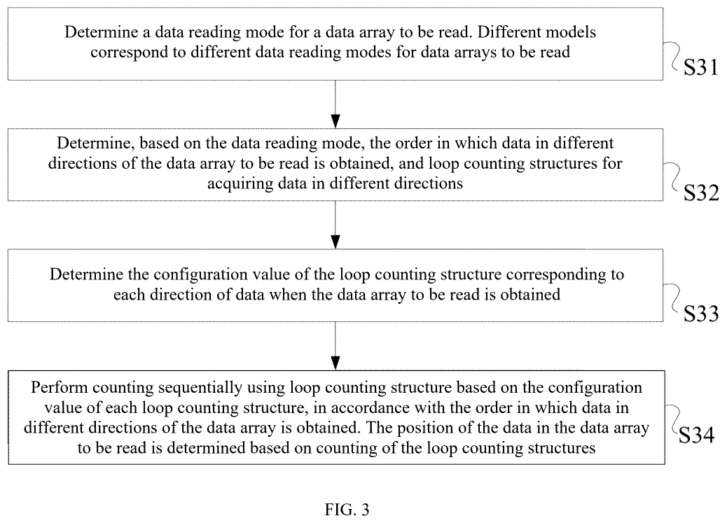

Certain embodiments disclose a data reading method, the flow chart of which is shown in FIG. 3. The method includes:
S31: Determine a data reading mode for a data array to be read. Different models correspond to different data reading modes for data arrays to be read;
S32: Determine, based on the data reading mode, the order in which data in different directions of the data array to be read is obtained, and loop counting structures for obtaining data in different directions;
S33: Determine the configuration value of the loop counting structure corresponding to each direction of data when the data array to be read is obtained;
S34: Perform counting sequentially using the corresponding loop counting structure based on the configuration value of each loop counting structure, in accordance with the order in which data in different directions of the data array to be read is obtained. The position of the data in the data array to be read is determined based on counting of the loop counting structures.

After determining the data reading mode for the data array to be read, the loop counting structures for data in different directions of the data array to be read are determined based on the data reading mode, and configuration values are set for the loop counting structures for each direction of data.

Configuration values may include maximum values, step values, initial values, and other configuration values, which are not limited here. The maximum value is the maximum value that the loop counting structure may reach. When the maximum value is reached, the loop counting structure switches to the next loop counting structure and the current loop counting structure is reset. The step value is the value by which the loop counting structure increments each time it counts. The initial value is the value at which the loop counting structure starts counting.

Depending on the data array to be read, the maximum value and step value of the loop counting structure for each direction of data may vary. Therefore, after determining the loop counting structures corresponding to the data array to be read, the corresponding configuration values are set for each loop counting structure so that counting based on the configured loop counting structure may meet the data reading requirements of the data array to be read.

The configuration values of the loop counting structures for data in different directions corresponding to the same data array to be read may be the same or different. In certain embodiments, for the same data array to be read, the maximum value of the first loop counting structure corresponding to the first direction is value 1, and the maximum value of the second loop counting structure corresponding to the second direction is value 2, and the values 1 and 2 are different. The step value of the first loop counting structure is step value 1, and the step value of the second loop counting structure is step value 2, and the step value 1 and step value 2 are the same.

In certain embodiments, for the same data array to be read, the maximum value of the first loop counting structure corresponding to the first direction is value 1, and the maximum value of the third loop counting structure corresponding to the third direction is value 3. Value 3 is the same as value 1, and the step value of the first loop counting structure is step value 1, and the step value of the third loop counting structure is step value 3. Step value 3 is different from step value 1.

In certain embodiments, for the same data array to be read, the maximum value of the first loop counting structure corresponding to the first direction is value 1, and the maximum value of the fourth loop counting structure corresponding to the fourth direction is value 4. Value 4 is different from value 1. The step value of the first loop counting structure is step value 1, and the step value of the fourth loop counting structure is step value 4. Step value 4 is different from step value 1.

In certain embodiments, according to the order in which data in different directions of the data array to be read is obtained, and based on the configuration values of each loop counting structure, counting is sequentially performed through the corresponding loop counting structures, and the position of the data in the data array to be read is determined based on counting of the loop counting structures. In certain embodiments, the following may be performed:

A first loop counting structure is determined according to the order in which data in different directions of the data array to be read is obtained; counting is performed through the first loop counting structure based on the step value of the first loop counting structure to determine the obtaining of data in the direction corresponding to the first loop counting structure; when the count value of the first loop counting structure reaches the maximum value of the first loop counting structure, a second loop counting structure is determined based on the obtaining order, and the count value of the second loop counting structure is adjusted; when the count values of the loop counting structures that obtain data in different directions reach the maximum value, it is determined that the obtaining of a portion of the data array to be read is completed.

When using loop counting structures to implement data reading according to a data reading mode, the corresponding loop counting structures are called sequentially according to the order in which data in different directions of the data array to be read is obtained.

When the first and second loop counting structures are determined according to the order in which data in different directions is obtained, the first loop counting structure is used to determine the obtaining of data in the direction corresponding to the first loop counting structure, and then the second loop counting structure is used to determine the obtaining of data in the direction corresponding to the second loop counting structure.

To count using the first loop counting structure, the configuration values of the first loop counting structure are set to determine the initial value, maximum value, and step value of the first loop counting structure. Then, starting from the initial value, the first loop counting structure is used to count according to the step value. For example, when the initial value is 0 and the step value is 3, the first loop counting structure starts counting at 0 and increments the count value by 3 each time it is counted. That is, the first count is 3, the second count is 6, and the third count is 9, until the count value reaches the maximum value.

When the count value of the first loop counting structure reaches its maximum value, counting begins using the second loop counting structure according to the order in which data is obtained in different directions. During counting using the second loop counting structure, it is determined whether the configuration value of the second loop counting structure has been set. The configuration value of the second loop counting structure may be set simultaneously with the configuration value of the first loop counting structure, or it may be set after the count value of the first loop counting structure reaches its maximum value. In certain embodiments, the configuration value of the second loop counting structure is set along with the configuration value of the first loop counting structure. This helps ensure that counting continues uninterrupted after the first loop counting structure begins counting, without waiting for the configuration values of other loop counting structures to be set.

After determining that the configuration value of the second loop counting structure has been set, counting begins at the initial value of the second loop counting structure and increments by the step value. For example, when the initial value is 4 and the step value is 1, the second loop counting structure begins counting at 4 and increments the count value by 1 each time, for example, the first count is 5, the second count is 6, and the third count is 7, until the count value reaches the maximum value set by the second loop counting structure.

When the count value of the second loop counting structure reaches the maximum value, counting continues through the loop counting structures arranged after the second loop counting structure according to the obtaining order of data in different directions until the count values of the loop counting structures according to the obtaining order of data in different directions all have reached the maximum value, at which time it may be determined that the obtaining of a part of the data array to be read is completed. Thereafter, when there is a need to obtain data, the next part of the data is obtained by continuing to count the loop counting structures.

Taking Transformer, a deep learning model based on the attention mechanism, as an example, the corresponding data reading mode determines the data in the BlockW and BlockH directions of the data array to be read. Therefore, at least the loop counting structure corresponding to the BlockW data and the loop counting structure corresponding to the BlockH data are determined. In addition, the unit loop counting structure Send Loop is also determined. The unit loop counting structure Send Loop is used for unit counting to read the data of a tile unit.

When it is determined that the data in the data array to be read is to be read, a data read request is input to the unit loop counting structure Send Loop to start counting. The Send Loop starts counting according to its step value. When the count reaches the maximum value of the Send Loop, a carry signal is output to the loop counting structure BlockW Loop corresponding to the BlockW direction data. When the step value of the BlockW Loop is 1, the BlockW Loop is incremented by 1. At the same time, the count value of the Send Loop is restored to its initial value. After that, the Send Loop continues to count according to its step value. When the count reaches the maximum value of the Send Loop, a carry signal is output to the loop counting structure BlockW Loop corresponding to the BlockW direction data. The BlockW Loop is incremented by 1 again until the count value of the BlockW Loop reaches the maximum value set for the BlockW Loop. The BlockW Loop outputs a carry signal to the loop counting structure BlockH Loop corresponding to the BlockH direction data. When the step value of the BlockH Loop is 1, the BlockH Loop is incremented by 1. At the same time, the Send Loop is restored to its initial value. The count values of the Send Loop and the BlockW Loop are restored to their initial values. After that, counting continues from the initial value of the Send Loop until the count value of the BlockH Loop reaches the maximum value set for the BlockH Loop. At this time, the loop counting structure stops counting, and the counting of the Send Loop, BlockW Loop, and BlockH Loop is completed.

In certain embodiments, using convolutional neural network model CNN as an example, based on its corresponding data reading mode, it is possible to determine the data to be obtained in the Cin, KernelH, BlockW, and BlockH directions of the data array to be read. Therefore, at least the loop counting structure (Cin Loop) corresponding to the Cin direction, the loop counting structure (KernelH Loop) corresponding to the KernelH direction, the loop counting structure (BlockW Loop) corresponding to the BlockW direction data, and the loop counting structure (BlockH Loop) corresponding to the BlockH direction data are determined. Furthermore, the unit loop counting structure (Send Loop) is also determined. The unit loop counting structure (Send Loop) is used for unit counting to read data from a tile.

When it is determined that the data in the data array to be read are to be read, a data read request is input to the unit cycle counting structure Send Loop to start counting. Send Loop starts counting according to its step value. When the count reaches the maximum value of Send Loop, a carry signal is output to Cin Loop. When the step value of Cin Loop is a, Cin Loop adds a. At the same time, the count value of Send Loop is restored to its initial value. After that, Send Loop continues to count according to its step value. When the count reaches the maximum value of Send Loop, a carry signal is output to the cycle counting structure Cin Loop corresponding to the Cin direction data. Cin Loop adds a again until the count value of Cin Loop reaches the maximum value set for Cin Loop. Cin Loop outputs a carry signal to KernelH Loop. When the step value of KernelH Loop is b, the count value of KernelH Loop adds b. At the same time, the count values of Send Loop and Cin Loop are restored to their initial values. After that, Send Loop The loop continues counting according to its step value until the count value of the KernelH Loop reaches its set maximum value. The KernelH Loop outputs a carry signal to the BlockW Loop. When the step value of the BlockW Loop is c, the count value of the BlockW Loop is increased by c until the count value of the BlockW Loop reaches its set maximum value. The BlockW Loop outputs a carry signal to the BlockH Loop. When the step value of the BlockH Loop is d, the count value of the BlockH Loop is increased by d until the count value of the BlockH Loop reaches its set maximum value. At this time, the cyclic counting structure stops counting, performing the counting of the Send Loop, Cin Loop, KernelH Loop, BlockW Loop, and BlockH Loop.

The present disclosure in certain embodiments discloses a data reading method, which determines a data reading mode of a data array to be read, where different models of data arrays to be read correspond to different data reading modes; based on the data reading mode, determines an obtaining order of data in different directions in the data array to be read, and loop counting structures for obtaining data in different directions; determines a configuration value of the loop counting structure corresponding to each direction of data when the data array to be read is obtained; according to the obtaining order of data in different directions in the data array to be read, based on the configuration value of each loop counting structure, counts in sequence through the corresponding loop counting structure, and determines the position of the data to be read in the data array to be read through counting of the loop counting structure. After determining the loop counting structures corresponding to the data array to be read, the present disclosure in certain embodiments further set a corresponding configuration value for each loop counting structure, so that when reading data from different data arrays to be read, different configuration values are set for the loop counting structures in different directions, thereby enabling obtaining of different data through the pre-set loop counting structures.

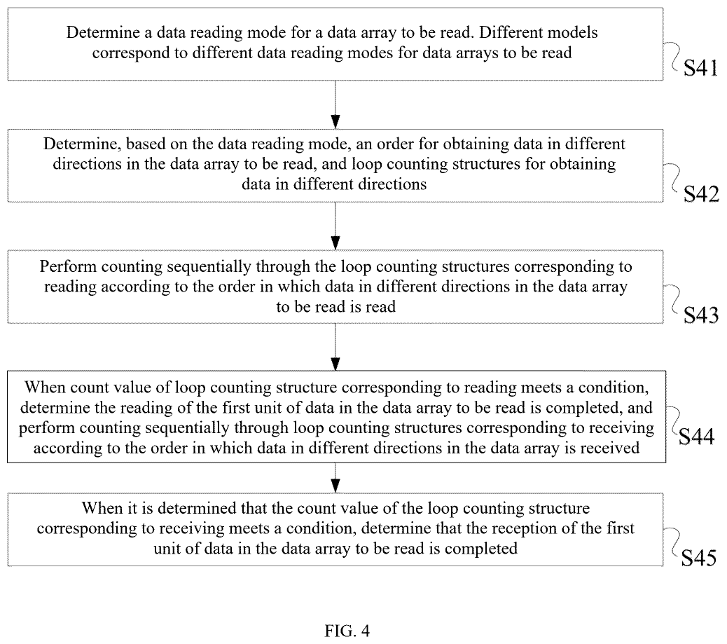

Certain embodiments disclose a data reading method, the flow chart of which is shown in FIG. 4, including:
S41: Determine a data reading mode for a data array to be read, where different models correspond to different data reading modes for data arrays to be read;
S42: Determine, based on the data reading mode, an order for obtaining data in different directions in the data array to be read, and loop counting structures for obtaining data in different directions;
S43: Perform counting sequentially through loop counting structures corresponding to reading according to the order in which data in different directions in the data array to be read is read (this order is also referred to as a “reading order”);
S44: When it is determined that the count value of the loop counting structure corresponding to reading meets a condition, determine that the reading of the first unit of data in the data array to be read is completed, and perform counting sequentially through loop counting structures corresponding to receiving according to the order in which data in different directions in the data array to be read is received (this order is also referred to as a “receiving order”);
S45: When it is determined that the count value of the loop counting structure corresponding to receiving meets a condition, determine that the reception of the first unit of data in the data array to be read is completed.

In certain embodiments, obtaining data from the data array to be read is divided into two operations: first, reading a portion of the data, and then, after the reading is completed, receiving the portion of data. Only then is the obtaining of the portion of data considered completed.

In certain embodiments, the loop counting structures used to retrieve data from the data array to be read are divided into loop counting structures used during the data reading process and loop counting structures used during the data receiving process. A loop counting structure corresponding to reading (i.e., used during data reading) is also referred to as a “reading loop counting structure,” and a loop counting structure corresponding to receiving (i.e., used during data receiving) is also referred to as a “receiving loop counting structure.”

In certain embodiments, the loop counting structures used during the data reading process may include at least the following: Send Loop, Cin Loop, KernelH Loop, BlockW Loop, and BlockH Loop. The loop counting structures used during the data receiving process may include at least the following: Mac Loop, Entry Loop, and Tile Loop.

Taking the attention-based deep learning model Transformer as an example, the loop counting structures during data reading process include the Send Loop, BlockW Loop, and BlockH Loop, and the loop counting structures during data receiving process include the Entry Loop and Tile Loop.

In certain embodiments, for sparse Transformer, the loop counting structures during data reading process include the Send Loop, BlockW Loop, and BlockH Loop, and the loop counting structures during data receiving process include the Mac Loop, Entry Loop, and Tile Loop.

In certain embodiments, for the convolutional neural network model CNN, the loop counting structures during data reading process include the Send Loop, Cin Loop, KernelH Loop, BlockW Loop, and BlockH Loop, and the loop counting structures during data receiving process include the Mac Loop, Entry Loop, and Tile Loop.

In certain embodiments, for a data reading device capable of obtaining data for the attention-based deep learning model Transformer, sparse Transformer, and the convolutional neural network model CNN, the loop counting structures may include one of each of the following: Send Loop, Cin Loop, KernelH Loop, BlockW Loop, BlockH Loop, Mac Loop, Entry Loop, and Tile Loop. This eliminates the need for a separate and independent set of loop counters for obtaining data for the attention-based deep learning model Transformer, a separate and independent set of loop counters for obtaining data for sparse Transformer, and a separate and independent set of loop counters for obtaining data for the convolutional neural network model CNN. By reusing these loop counting structures, the data corresponding to different models may be obtained, saving the area occupied by the circuits corresponding to the loop counters for reading the data.

Taking Transformer, a deep learning model based on the attention mechanism, as an example, this is illustrated:

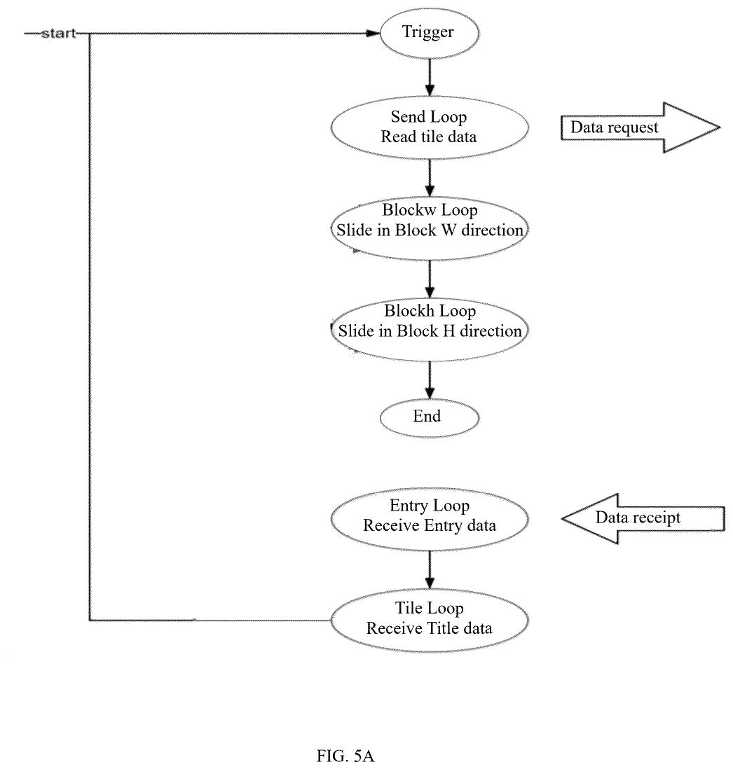

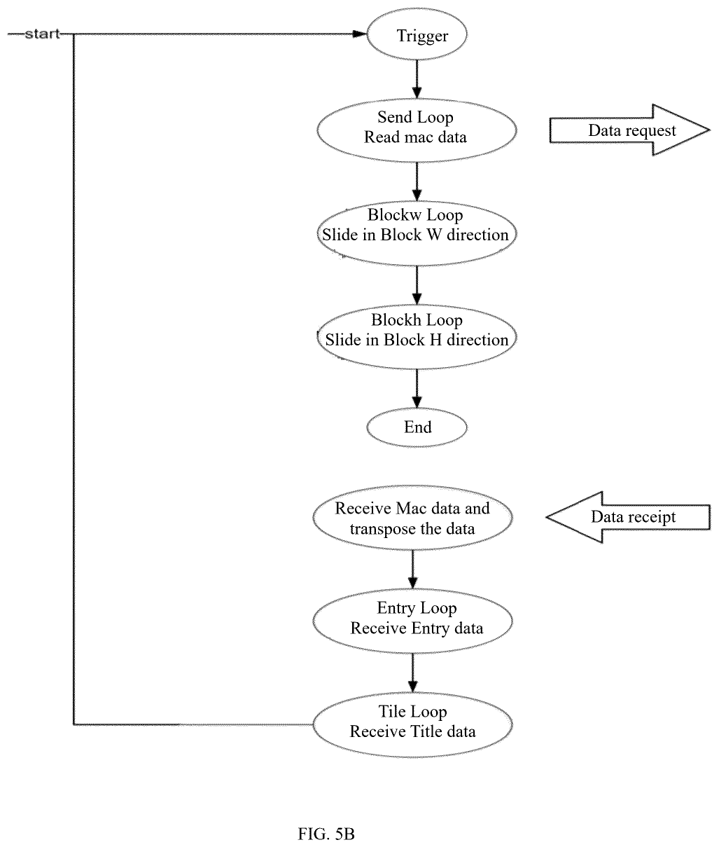

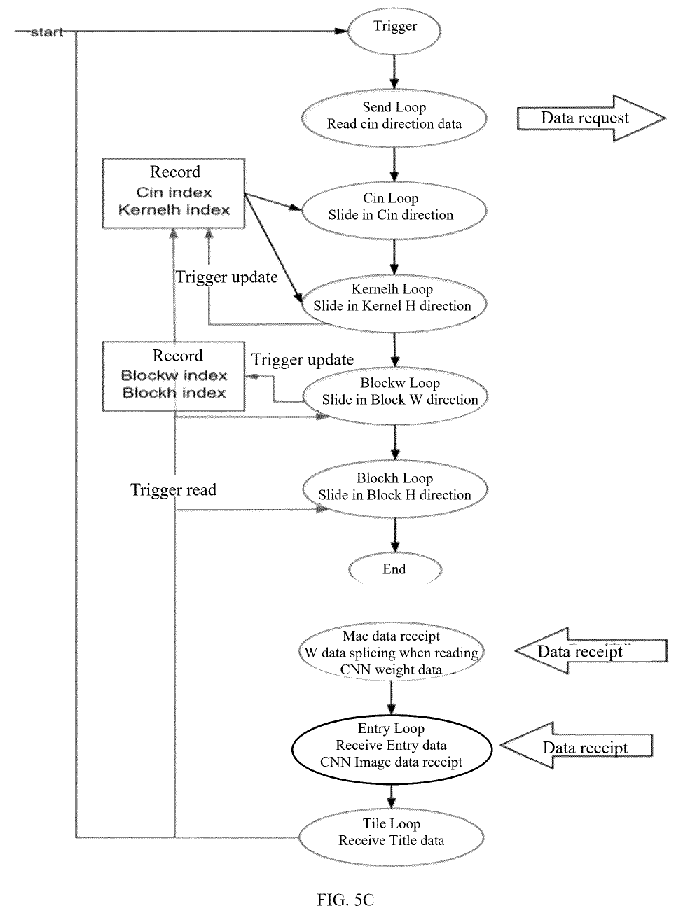

In certain embodiments, FIG. 5A shows a schematic diagram of data obtaining. The data array to be read corresponding to Transformer, a deep learning model based on the attention mechanism, is determined. The corresponding loop counting structures, namely, the Send Loop, BlockW Loop, BlockH Loop, Entry Loop, and Tile Loop, are selected. A data obtaining request is generated to trigger the Send Loop to start counting. When the Send Loop count reaches its maximum value, the BlockW Loop is triggered to start counting. A Data request is output to request the reading of a tile (parallel data block). Subsequently, the BlockW Loop counts the data array to be read in the BlockW direction, and the BlockH Loop counts the data array to be read in the BlockH direction. When the Send Loop, BlockW Loop, and BlockH Loop all reach their configured maximum values, the loop counting structures for data reading perform their counting.

Each time the Send Loop transitions, it issues a Data request. Sliding in the BlockW direction traverses the data in that direction, and sliding in the BlockH direction traverses the data in that direction, thus traversing all the data to be read.

Based on the output of the Data request, the data reader receives the data, and the loop counting structure for receiving data begins counting. During the data receiving process, the Entry Loop begins counting. When the Entry Loop count reaches its maximum value, one entry has been received, recording a row of data. At this point, the Entry Loop outputs a carry signal to the Tile Loop, and the Tile Loop begins counting again. When the Tile Loop count reaches its maximum value, a column of data is received through the Tile Loop. When both the Entry Loop and Tile Loop counts reach their maximum values, one tile of data has been received, indicating that the first unit of data has been received.

After the data reception of a Tile is completed, the loop counting structure for reading data is triggered to continue sending a Tile data request. After the data array to be read is divided into multiple tiles and the data is read and received tile by tile, the received data of each tile is spliced together to obtain the data array received, thereby achieving complete obtaining of the data array to be read.

Taking sparse Transformer as an example:

In certain embodiments, and as shown in FIG. 5B, the data array to be read corresponding to sparse Transformer is determined, and the corresponding loop counting structures are selected: Send Loop, BlockW Loop, BlockH Loop, Mac Loop, Entry Loop, and Tile Loop. A data obtaining request is generated to trigger the Send Loop to start counting. When the Send Loop count reaches its maximum, the count is carried over to the BlockW Loop, causing the BlockW Loop to start counting. When the BlockW Loop count reaches its maximum, the count is carried over to the BlockH Loop, causing the BlockH Loop count to reach its maximum. When the BlockH Loop count reaches its maximum, the data reading process is completed. During the counting process, when the sliding reaches the data size of one tile, a data request is output to request the data of one tile.

The data reading process and data receiving process differ from the deep learning Transformer model based on the attention mechanism in that a data transposition step is added during the data receiving process. The other steps are the same as the above example.

Among them, Mac Loop is responsible for receiving data, transposing the data, and then outputting it to Entry Loop and Tile Loop to realize the reception of a Tile data.

Taking convolutional neural network model CNN as an example:

In certain embodiments, and as shown in FIG. 5C, the data array to be read corresponding to convolutional neural network model CNN is determined, and the corresponding loop counting structures are selected, namely: Send Loop, Cin Loop, KernelH Loop, BlockW Loop, BlockH Loop, Mac Loop, Entry Loop, and Tile Loop. A data obtaining request is generated to trigger the Send Loop to start counting. When the Send Loop count reaches its maximum value, the Cin Loop is triggered to start counting. Based on the Cin Loop count, the data array to be read slides in the Cin direction. When the Cin Loop count reaches its maximum value, the KernelH Loop is carried forward, and the KernelH Loop starts counting. Based on the KernelH Loop count, the data array to be read slides in the KernelH direction. When the KernelH Loop count reaches its maximum value, the BlockW Loop is carried forward, and the BlockW Loop starts counting. Based on the BlockW Loop count, the data array to be read slides in the BlockW direction. When the BlockW Loop count reaches its maximum value, the BlockW Loop counts forward. When the count in the loop reaches its maximum value, it carries over to the BlockH loop, which begins counting. Using the count in the BlockH loop, the loop slides in the BlockH direction of the data array to be read. When the count in the BlockH loop reaches its maximum value, the data reading process is completed. During the counting process, when the loop reaches the data size of a tile, a data request is output to request the data of a tile.

Based on the output of the data request, the data reading device receives the data, and the loop counting structure for receiving data begins counting. During the data reception process, the Mac loop reads weighted data for data splicing. The Mac loop may also perform data transposition, multiplexing the Mac loops to achieve different functions in the data reception process. Subsequently, as in the above example, the Entry loop and Tile loop count to perform the reception of a tile of data.

In certain embodiments, the process of reading the data array to be read of the convolutional neural network model CNN may include:

When it is determined that the reading of the first unit of data in the data array to be read is completed, storing the count value of the loop counting structure corresponding to the read operation in a storage structure; when it is determined that the reception of the first unit of data in the data array to be read is completed, updating the count value stored in the storage structure to the loop counting structure corresponding to the read operation, and controlling the loop counting structure corresponding to the read operation to start counting from the count value stored at a particular position to determine the reading of the second unit of data in the data array to be read.

In certain embodiments, during the process of reading the data array to be read of the convolutional neural network model CNN, the system stores the count values corresponding to the read and received data to help ensure the accuracy of the data reading position.

When sending a data request, the position of the tile data requested in each direction is recorded, that is, the count value of each loop counting structure when sending the data request is stored, such as: the count value index of the Cin Loop, the count value index of the KernelH Loop, the count value index of the BlockW Loop, and the count value index of the BlockH Loop when sending the Data request are stored in the storage structure, and then data is received based on the data request;

After data reception is completed, the Send Loop is triggered to continue counting to continue reading the data in the data array to be read. At this time, the loop counting structure is triggered to read the count value from the storage structure to determine the starting position for data reading. In certain embodiments, the Cin Loop is triggered to read the Cin Loop count value index recorded from the storage structure, so that the Cin Loop starts counting from the Cin Loop count value index stored in the storage structure; the KernelH Loop is triggered to read the KernelH Loop count value index recorded from the storage structure, so that the KernelH Loop starts counting from the KernelH Loop count value index stored in the storage structure; the BlockW Loop is triggered to read the BlockW Loop count value index recorded from the storage structure, so that the BlockW Loop starts counting from the BlockW Loop count value index stored in the storage structure; and the BlockH Loop is triggered to read the BlockH Loop count value index recorded from the storage structure, so that the BlockH Loop starts counting from the BlockH Loop count value index stored in the storage structure.

In certain embodiments, when it is determined that the data array to be read is a specific type of data, when it is determined that the reading of the first unit data in the data array to be read is completed, the count value of the corresponding loop counting structure is stored in the storage structure, and when it is determined that the reception of the first unit data in the data array to be read is completed, the count value stored in the storage structure is updated to the loop counting structure corresponding to the reading.

In certain embodiments, the data array to be read from the convolutional neural network model CNN is of a specific type of data. That is, the corresponding count value is stored only when the data array to be read corresponds to the convolutional neural network model CNN. This step may not be required for data arrays corresponding to sparse Transformer or Transformer model based on an attention mechanism.

The data reading method disclosed in certain embodiments determines a data reading mode for the data array to be read, where different models correspond to different data reading modes for data arrays to be read. Based on the data reading mode, the data array to be read has different directions, as well as loop counting structures for obtaining data in different directions. The data array to be read in the order in which the data in different directions in the data array to be read is counted sequentially through loop counting structures corresponding to reading. When it is determined that the count value of the loop counting structure corresponding to reading satisfies a condition, the reading of the first unit of data in the data array to be read is determined to have completed. The data array to be read in the order in which the data in different directions in the data array to be read is counted sequentially through loop counting structures corresponding to receiving. When it is determined that the count value of the loop counting structure corresponding to receiving satisfies a condition, the reception of the first unit of data in the data array to be read is determined to have completed. When obtaining data through a loop counting structure, this solution reads the first unit data through the loop counting structures corresponding to reading. After the reading is completed, the first unit data is received through the loop counting structures corresponding to receiving to achieve the obtaining of the first unit data in the data array to be read, thereby helping ensure the obtaining of data corresponding to different models.

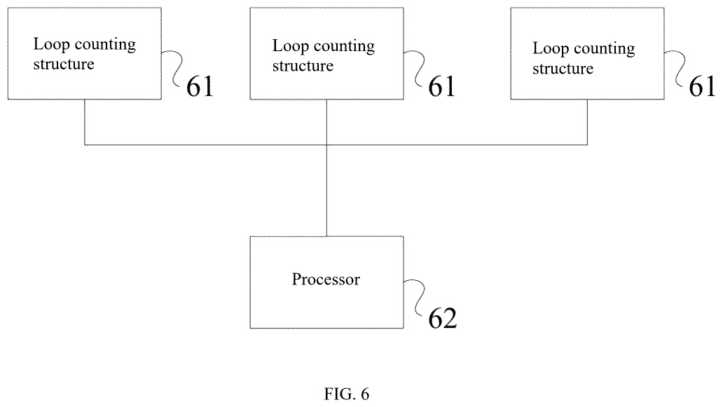

Certain embodiments disclose a data reading device, the structure of which is shown in FIG. 6. The device includes multiple loop counting structures 61 and a processor 62.

The processor 62 is configured to determine a data reading mode for a data array to be read. Different models of data arrays to be read correspond to different data reading modes. Based on the data reading mode, the processor 62 determines the order in which data in different directions in the data array to be read is obtained, as well as the loop counting structures 61 for obtaining data in different directions. Counting is performed sequentially using the corresponding loop counting structures 61 according to the obtaining order of data in different directions in the data array to be read, and the positions of the data to be read in the data array to be read are determined based on counting of the loop counting structures 61.

In certain embodiments, the data reading device disclosed in certain embodiments may include multiple switches, respectively disposed between the loop counting structures, and the on/off states of the switches between the different loop counting structures can be controlled based on the data reading mode and the obtaining order.

In certain embodiments, the data reading device disclosed in certain embodiments may include:

A storage structure for storing the count values of each loop counting structure.

In certain embodiments, the storage structure in the data reading device disclosed in certain embodiments is configured to:

When it is determined that the reading of the first unit of data in the data array to be read is completed, store the count value of the loop counting structure corresponding to the read operation in the storage structure; when it is determined that the reception of the first unit of data in the data array to be read is completed, update the count value stored in the storage structure to the loop counting structure corresponding to the read operation, and control the loop counting structure corresponding to the read operation to start counting from the count value stored at a particular position to determine the reading of the second unit of data in the data array to be read.

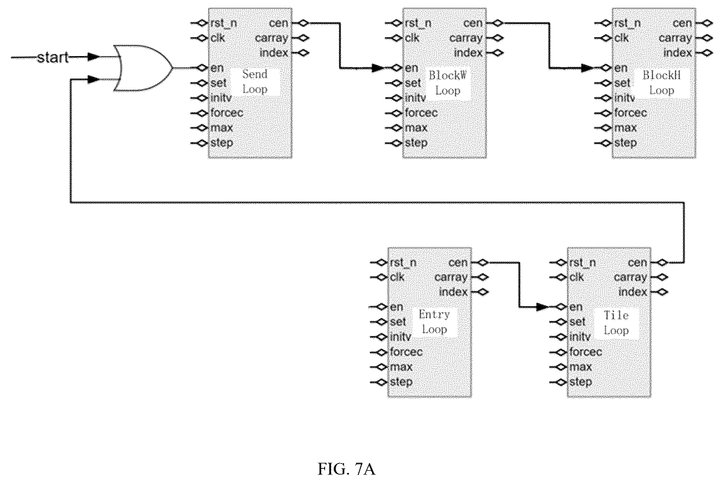

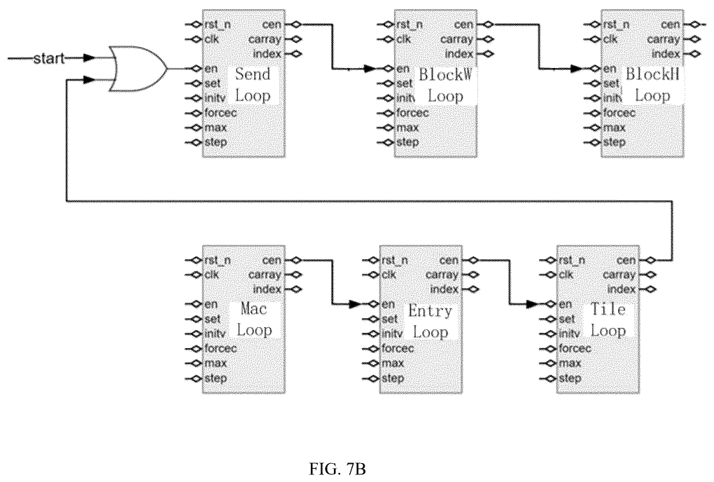

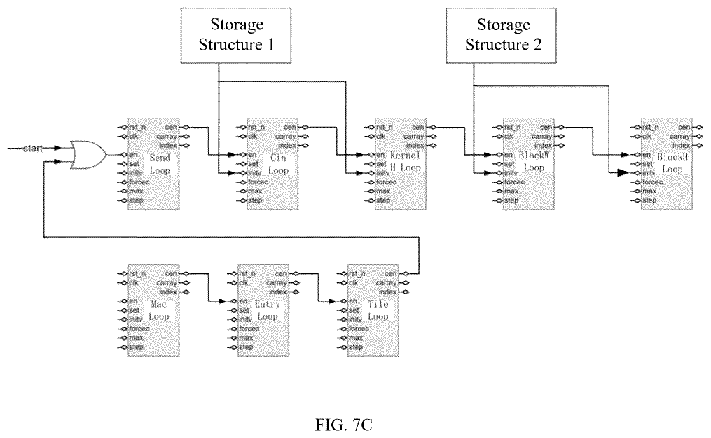

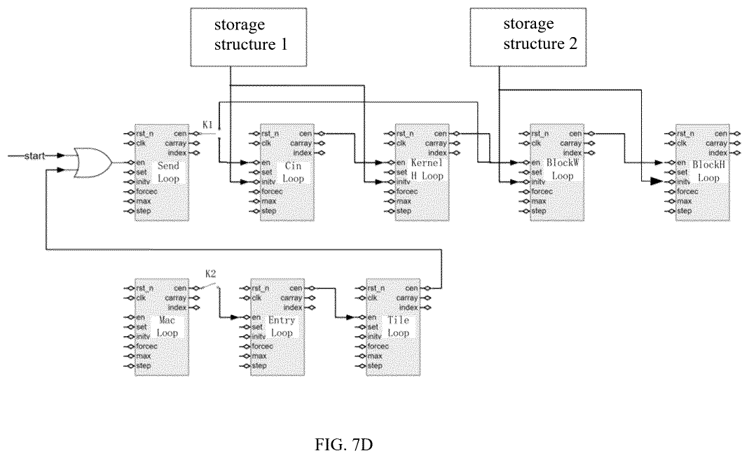

When the data array to be read corresponds to Transformer deep learning model based on an attention mechanism, the circuit diagram including loop counting structures and storage structures may be shown in FIG. 7A (the processor is not shown), including: Send Loop, BlockW Loop, BlockH Loop, Entry Loop, and Tile Loop. In each loop counting structure, en is the enable interface, cen is the enable interface for outputting a carry signal, and intiv is the interface for outputting the count value.

When the data array to be read corresponds to sparse Transformer model, the circuit diagram including loop counting structures and storage structures may be shown in FIG. 7B (the processor is not shown), including: Send Loop, BlockW Loop, BlockH Loop, Mac Loop, Entry Loop, and Tile Loop.

When the data array to be read corresponds to convolutional neural network model CNN, the circuit diagram including loop counting structures and storage structures may be shown in FIG. 7C (the processor is not shown), including: Send Loop, Cin Loop, KernelH Loop, BlockW Loop, BlockH Loop Loop, Mac Loop, Entry Loop, Tile Loop, storage structure 1 and storage structure 2, where storage structure 1 and storage structure 2 may be different parts of the same storage structure or different storage structures, which is not limited here.

In certain embodiments, the circuit diagram of the data reading device disclosed in certain embodiments may be shown in FIG. 7D (the processor is not shown), including: a Send Loop, a Cin Loop, a KernelH Loop, a BlockW Loop, a BlockH Loop, a Mac Loop, an Entry Loop, a Tile Loop, a first switch K1, a second switch K2, a storage structure 1, and a storage structure 2. The first switch K1 is a single-pole double-throw switch, whose input end is connected to the cen interface of the Send Loop, whose first output end is connected to the en interface of the Cin Loop, and whose second output end is connected to the en interface of the BlockW Loop. The second switch K2 is a single-pole single-throw switch, whose one end is connected to the cen interface of the Mac Loop, and whose other end is connected to the en interface of the Entry Loop.

When the data array to be read is data corresponding to deep learning model Transformer based on the attention mechanism, the first switching switch K1 and the second switching switch K2 are switched so that the circuit diagram corresponding to FIG. 7D is transformed into that shown in FIG. 7A; when the data array to be read is data corresponding to sparse Transformer model, the first switching switch K1 and the second switching switch K2 are switched so that the circuit diagram corresponding to FIG. 7D is transformed into that shown in FIG. 7B; when the data array to be read is data corresponding to the convolutional neural network model CNN, the first switching switch K1 and the second switching switch K2 are switched so that the circuit diagram corresponding to FIG. 7D is transformed into that shown in FIG. 7C.

The data reading device disclosed in certain embodiments is implemented based on the data reading method disclosed and relevant descriptions are not repeated here for brevity.

The data reading device disclosed in certain embodiments determines a data reading mode for a data array to be read, where different models correspond to different data reading modes for data arrays to be read; based on the data reading mode, determines an order for obtaining data in different directions in the data array to be read, as well as loop counting structures for obtaining data in different directions; and sequentially counts data using the corresponding loop counting structures according to the order in which data in different directions in the data array to be read, determining the position of the data to be read in the data array to be read based on counting of the loop counting structures. This solution provides loop counting structures. When data in the data array to be read is to be read, the corresponding loop counting structures are obtained based on the data reading mode of the data array to be read, and counting is sequentially performed using the corresponding loop counting structures in order to determine the position of the data to be read in the data array to be read. This helps enable data reading in different data reading modes to be achieved through the reuse of the loop counting structures. This reuse of the loop counting structures eliminates the need for a separate and independent data reading process for each data reading mode, thereby reducing the circuit space occupied by the small loop counter including loop counting structures.

The device embodiments described above are merely illustrative. The units described as separate components may or may not be physically separate, and the components shown as units may or may not be physical units, for example, they may be located in a single location or distributed across multiple network units. Some or all of these modules may be selected to achieve the objectives of certain embodiments. Furthermore, in the drawings of the device embodiments provided herein, the connections between modules indicate a communication connection, which may be implemented as one or more communication buses or signal lines.

Those skilled in the technical field understand that certain embodiments of the present disclosure may be implemented using software plus necessary general-purpose hardware, or alternatively, using dedicated hardware, including application-specific integrated circuits, dedicated CPUs, dedicated memories, and dedicated components. Functions performed by a computer program may be implemented using corresponding hardware. Hardware structures used to implement the functions may vary, such as analog circuits, digital circuits, or dedicated circuits. Software implementation may be used. The technical solution may be embodied in the form of a software product. The computer software product is stored in a readable storage medium, such as a computer floppy disk, USB flash drive, mobile hard disk, ROM, RAM, magnetic disk or optical disk, or the like, and includes a number of instructions for enabling a computer device (which may be a personal computer, training equipment, or network equipment, or the like) to execute the data reading method.

Certain embodiments may be implemented using software, hardware, firmware, or any combination thereof. When implemented using software, the embodiments may be implemented in the form of a computer program product.

The computer program product includes one or more computer instructions. When the computer program instructions are loaded and executed on a computer, the processes or functions described in the embodiments of the present application are generated in whole or in part. The computer may be a general-purpose computer, a special-purpose computer, a computer network, or other programmable device. The computer instructions may be stored in a computer-readable storage medium or transmitted from one computer-readable storage medium to another. For example, the computer instructions may be transmitted from one website, computer, training device, or data center to another website, computer, training device, or data center via wired (for example, coaxial cable, optical fiber, digital subscriber line (DSL)) or wireless (for example, infrared, wireless, microwave, or the like) methods. The computer-readable storage medium may be any available medium that may be stored on a computer or a data storage device such as a training device or data center that integrates one or more available media. The available medium may be a magnetic medium (for example, a floppy disk, a hard disk, a magnetic tape), an optical medium (for example, a DVD), or a semiconductor medium (for example, a solid state disk (SSD)).

What is claimed is:

1. A data reading method comprising:
determining a data reading mode for a data array;
determining, based on the data reading mode, an obtaining order for obtaining data in different directions in the data array, and a plurality of loop counting structures for obtaining the data in the different directions; and
performing, according to the obtaining order, counting sequentially through corresponding ones of the loop counting structures, a position of target data in the data array being determined based on counting of the loop counting structures.

2. The method of claim 1, wherein performing counting includes:
determining configuration values of the loop counting structures corresponding to the different directions, respectively, when the data array is being obtained; and
performing counting sequentially through the corresponding ones of the loop counting structures according to the obtaining order and based on the configuration values.

3. The method of claim 2, wherein performing counting sequentially through the corresponding ones of the loop counting structures according to the obtaining order and based on the configuration values includes:
determining a first loop counting structure from the plurality of loop counting structures according to the obtaining order;
performing counting through the first loop counting structure based on a step value of the first loop counting structure, to obtain data in a direction corresponding to the first loop counting structure; and
in response to a count value of the first loop counting structure reaching a maximum value, determining a second loop counting structure from the plurality of loop counting structure and adjusting a count value of the second loop counting structure.

4. The method of claim 1, wherein performing counting includes:
performing, according to an order in which the data in the different directions is read, counting sequentially through first loop counting structures, of the plurality of loop counting structures, that correspond to reading;
in response to a first count value of the first loop counting structures meeting a first condition, determining that reading of a unit of data in the data array is completed, and performing, according to an order in which the data in the different directions is received, counting sequentially through second loop counting structures, of the plurality of loop counting structures, that correspond to receiving; and
in response to a second count value of the second loop counting structures meeting a second condition, determining that receiving of the unit of data is completed.

5. The method of claim 4,
wherein the unit of data is a first unit of data;
the method further comprising:
in response to determining that reading of the first unit of data is completed, storing the first count value in a storage structure; and
in response to determining that receiving of the first unit of data is completed, updating a count value stored in the storage structure to a loop structure corresponding to reading to control the loop structure corresponding to reading to start counting from the count value, to read a second unit of data in the data array.

6. The method of claim 5, wherein determining whether reading of the first unit of data is completed and determining whether receiving of the first unit of data is completed are performed in response the data array being of a specific type.

7. The method of claim 1, further comprising:
controlling a switch arranged between two of the loop counting structures to be in an on state or an off state based on the data reading mode and the obtaining order.

8. A data reading device comprising:
a plurality of loop counting structures, different ones of the loop counting structures corresponding to different data reading modes; and
a processor configured to:
determine a data reading mode for a data array;
determine, based on the data reading mode, an obtaining order for obtaining data in different directions in the data array, and the plurality of loop counting structures for obtaining the data in the different directions; and
perform, according to the obtaining order, counting sequentially through corresponding ones of the loop counting structures, a position of target data in the data array being determined based on counting of the loop counting structures.

9. The device of claim 8, wherein the processor is further configured to, when performing counting:
determine configuration values of the loop counting structures corresponding to the different directions, respectively, when the data array is being obtained; and
perform counting sequentially through the corresponding ones of the loop counting structures according to the obtaining order and based on the configuration values.

10. The device of claim 9, wherein the processor is further configured to, when performing counting sequentially through the corresponding ones of the loop counting structures according to the obtaining order and based on the configuration values:
determine a first loop counting structure from the plurality of loop counting structures according to the obtaining order;
perform counting through the first loop counting structure based on a step value of the first loop counting structure, to obtain data in a direction corresponding to the first loop counting structure; and
in response to a count value of the first loop counting structure reaching a maximum value, determine a second loop counting structure from the plurality of loop counting structure and adjusting a count value of the second loop counting structure.

11. The device of claim 8, wherein the processor is further configured to, when performing counting:
perform, according to an order in which the data in the different directions is read, counting sequentially through first loop counting structures, of the plurality of loop counting structures, that correspond to reading;
in response to a first count value of the first loop counting structures meeting a first condition, determine that reading of a unit of data in the data array is completed, and perform, according to an order in which the data in the different directions is received, counting sequentially through second loop counting structures, of the plurality of loop counting structures, that correspond to receiving; and
in response to a second count value of the second loop counting structures meeting a second condition, determine that receiving of the unit of data is completed.

12. The device of claim 11, further comprising:
a storage structure;
wherein:
the unit of data is a first unit of data; and
the processor is further configured to:
in response to determining that reading of the first unit of data is completed, store the first count value in the storage structure; and
in response to determining that receiving of the first unit of data is completed, update a count value stored in the storage structure to a loop structure corresponding to reading to control the loop structure corresponding to reading to start counting from the count value, to read a second unit of data in the data array.

13. The device of claim 12, wherein the processor is further configured to determine whether reading of the first unit of data is completed and determine whether receiving of the first unit of data is completed in response the data array being of a specific type.

14. The device of claim 8, further comprising:
a plurality of switches each arranged between two of the loop counting structures;
wherein the processor is further configured to control each of the switches to be in an on state or an off state based on the data reading mode and the obtaining order.

15. The device of claim 8, further comprising:
a storage structure configured to store count values of the loop counting structures.

16. A non-transitory computer-readable storage medium storing instructions that, when executed by a processor, cause the processor to:
determine a data reading mode for a data array;
determine, based on the data reading mode, an obtaining order for obtaining data in different directions in the data array, and a plurality of loop counting structures for obtaining the data in the different directions; and
perform, according to the obtaining order, counting sequentially through corresponding ones of the loop counting structures, a position of target data in the data array being determined based on counting of the loop counting structures.

17. The storage medium of claim 16, wherein the instructions further cause the processor to, when performing counting:
determine configuration values of the loop counting structures corresponding to the different directions, respectively, when the data array is being obtained; and
perform counting sequentially through the corresponding ones of the loop counting structures according to the obtaining order and based on the configuration values.

18. The storage medium of claim 17, wherein the instructions further cause the processor to, when performing counting sequentially through the corresponding ones of the loop counting structures according to the obtaining order and based on the configuration values:
determine a first loop counting structure from the plurality of loop counting structures according to the obtaining order;
perform counting through the first loop counting structure based on a step value of the first loop counting structure, to obtain data in a direction corresponding to the first loop counting structure; and
in response to a count value of the first loop counting structure reaching a maximum value, determine a second loop counting structure from the plurality of loop counting structure and adjusting a count value of the second loop counting structure.

19. The storage medium of claim 16, wherein the instructions further cause the processor to, when performing counting:
perform, according to an order in which the data in the different directions is read, counting sequentially through first loop counting structures, of the plurality of loop counting structures, that correspond to reading;
in response to a first count value of the first loop counting structures meeting a first condition, determine that reading of a unit of data in the data array is completed, and perform, according to an order in which the data in the different directions is received, counting sequentially through second loop counting structures, of the plurality of loop counting structures, that correspond to receiving; and
in response to a second count value of the second loop counting structures meeting a second condition, determine that receiving of the unit of data is completed.

20. The storage medium of claim 19, wherein:
the unit of data is a first unit of data; and
the instructions further cause the processor to, when:
in response to determining that reading of the first unit of data is completed, store the first count value in the storage structure; and
in response to determining that receiving of the first unit of data is completed, update a count value stored in the storage structure to a loop structure corresponding to reading to control the loop structure corresponding to reading to start counting from the count value, to read a second unit of data in the data array.
